(19) United States
(12) Patent Application Publication
(10) Pub. No.: US 2026/0282275 A1
(43) Pub. Date: Sep. 17, 2026

(54) LIQUID COOLING SYSTEM

(71) Applicants: INVENTEC (PUDONG) TECHNOLOGY CORPORATION, Shanghai (CN); INVENTEC CORPORATION, Taipei City (TW)

(72) Inventors: Qi ZHANG, Shanghai (CN); Jingnan ZHAO, Shanghai (CN); Wenyan HUANG, Shanghai (CN)

(73) Assignees: INVENTEC (PUDONG) TECHNOLOGY CORPORATION, Shanghai (CN); INVENTEC CORPORATION, Taipei City (TW)

(21) Appl. No.: 19/195,411

(22) Filed: Apr. 30, 2025

(30) Foreign Application Priority Data
Mar. 12, 2025 (CN) 202510294035.9

(51) Int. Cl. H05K 7/20

(52) U.S. Cl. CPC H05K 7/20254; H05K 7/20272; H05K 7/20454

(57) ABSTRACT

A liquid cooling system includes first liquid cooling plates and liquid cooling modules. The first liquid cooling plates are configured to respectively thermally contact first heating elements. The first liquid cooling plates are connected in series and in fluid communication with each other. The liquid cooling modules connected in series and in fluid communication with each other. Each liquid cooling module includes two divergence parts and second liquid cooling plates. The divergence parts are in fluid communication with the first liquid cooling plates. Each divergence part has divergence holes. The second liquid cooling plates are configured to thermally contact second heating elements. The second liquid cooling plates are disposed between the divergence parts and are in fluid communication with the divergence parts via the divergence holes, respectively. The first liquid cooling plates and the liquid cooling modules are connected in series and in fluid communication with each other.

### CROSS-REFERENCE TO RELATED APPLICATIONS

This non-provisional application claims priority under 35 U.S.C. § 119(a) on Patent Application No(s). 202510294035.9 filed in China, P.R.C. on Mar. 12, 2025, the entire contents of which are hereby incorporated by reference.

### BACKGROUND OF THE INVENTION

### Technical Field of the Invention

The present disclosure relates to a liquid cooling system, more particularly a liquid cooling system for memory modules.

### Description of the Related Art

With technological advancements, memory modules, such as those conforming to the DIMM (Dual In-line Memory Module) standard, are required to process significantly larger amounts of data. This increase in processing capacity leads to higher power consumption, which in turn generates substantial waste heat.

However, in conventional servers, air cooling systems are predominantly used to direct airflow over the memory modules to dissipate heat. Nonetheless, such air cooling systems are no longer sufficient to provide timely heat dissipation for high-power memory modules.

### SUMMARY OF THE INVENTION

The present disclosure provides a liquid cooling system that offers an effective cooling mechanism for memory modules.

According to one aspect of the present disclosure, a liquid cooling system includes a plurality of first liquid cooling plates and a plurality of liquid cooling modules. The plurality of first liquid cooling plates are configured to respectively thermally contact a plurality of first heating elements, and the plurality of first liquid cooling plates are connected in series and in fluid communication with each other. The plurality of liquid cooling modules connected in series and in fluid communication with each other. Each of the plurality of liquid cooling modules includes two divergence parts and a plurality of second liquid cooling plates. The two divergence parts are in fluid communication with the plurality of first liquid cooling plates, and each of the two divergence parts has a plurality of divergence holes. The plurality of second liquid cooling plates are configured to thermally contact a plurality of second heating elements, and the plurality of second liquid cooling plates are disposed between the two divergence parts and are in fluid communication with the two divergence parts via the plurality of divergence holes, respectively. The plurality of first liquid cooling plates and the plurality of liquid cooling modules are connected in series and in fluid communication with each other.

According to the liquid cooling system discussed above, in addition to using the first liquid cooling plates to absorb the heat generated by the first heating elements, the first liquid cooling plates are also connected in series to the second liquid cooling plates. This design enables the second liquid cooling plates to absorb the heat generated by the second heating elements during operation, thereby preventing heat accumulation around the second heating elements that could otherwise affect their normal functioning.

### BRIEF DESCRIPTION OF THE DRAWINGS

The present disclosure will become more fully understood from the detailed description given hereinbelow and the accompanying drawings which are given by way of illustration only and thus are not intending to limit the present disclosure and wherein:

FIG. 1 is a perspective view of a liquid cooling system according to one embodiment of the present disclosure;

FIG. 2 is a partially exploded view of the liquid cooling system in FIG. 1; and

FIG. 3 is a partially exploded view of partial components of the liquid cooling system in FIG. 2.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

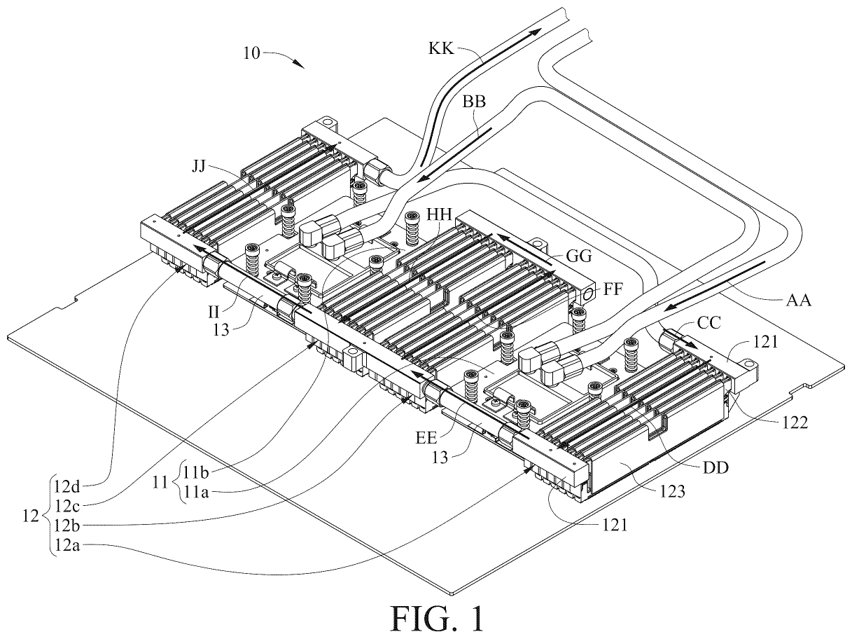

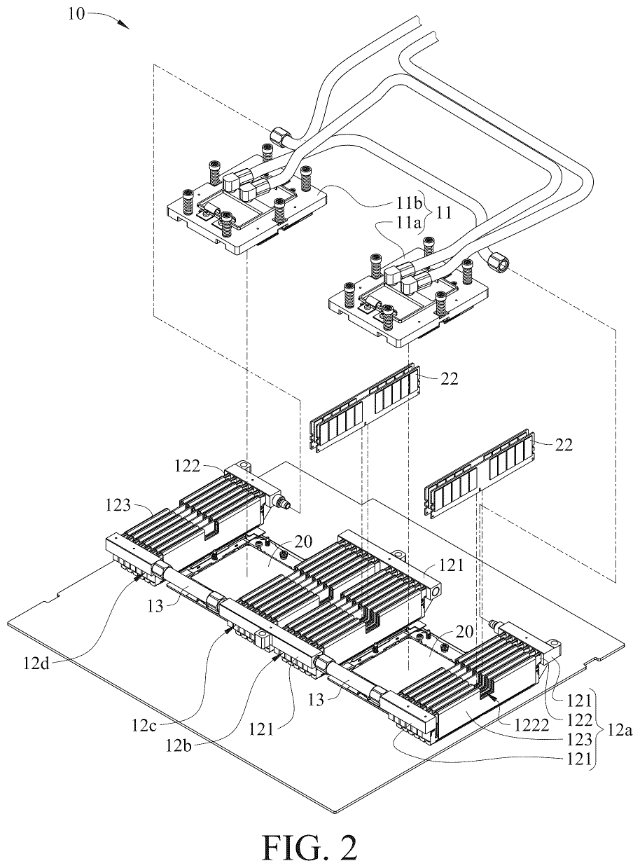

Please refer to FIG. 1 to FIG. 2, where FIG. 1 is a perspective view of a liquid cooling system according to one embodiment of the present disclosure and FIG. 2 is a partially exploded view of the liquid cooling system in FIG. 1.

A liquid cooling system 10 provided in this embodiment may be, for example, applied within a server chassis. The liquid cooling system 10 includes a plurality of first liquid cooling plates 11, a plurality of liquid cooling modules 12, and a plurality of communication pipes 13.

The quantity of the first liquid cooling plates 11 may be, for example, two. Specifically, the first liquid cooling plates 11 include a front first liquid cooling plate 11a and a rear first liquid cooling plate 11b. The front first liquid cooling plate 11a and the rear first liquid cooling plate 11b are connected in series and in fluid communication with each other. The front first liquid cooling plate 11a and the rear first liquid cooling plate 11b are configured to respectively thermally contact a plurality of first heating elements 20, wherein the first heating elements 20 may be, for example, central processing units (CPUs).

The quantity of the liquid cooling modules 12 may be, for example, four. Specifically, the liquid cooling modules 12 include a first liquid cooling module 12a, a second liquid cooling module 12b, a third liquid cooling module 12c, and a fourth liquid cooling module 12d. The first liquid cooling module 12a, the second liquid cooling module 12b, the third liquid cooling module 12c, and the fourth liquid cooling module 12d are connected in series and in fluid communication with each other.

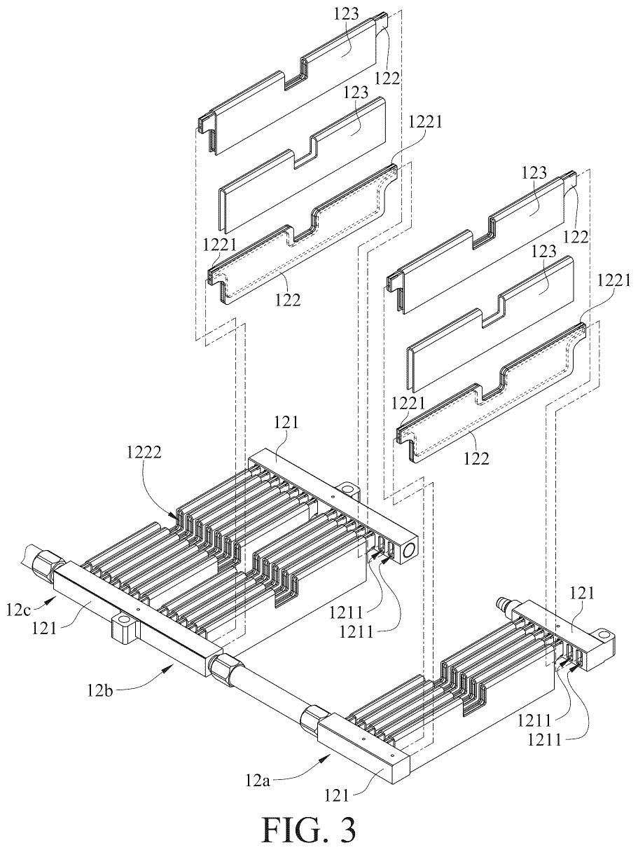

Please refer to FIG. 3 along with FIG. 1 and FIG. 2, where FIG. 3 is a partially exploded view of partial components of the liquid cooling system in FIG. 2.

Each liquid cooling module 12 includes two divergence parts 121, a plurality of second liquid cooling plates 122, and a plurality of flexible thermal conductive pads 123.

The divergence parts 121 may be, for example, made of copper. The divergence parts 121 are in fluid communication with the first liquid cooling plates 11. Each divergence part 121 has a plurality of divergence holes 1211, and the quantity of the divergence holes 1211 in each divergence part 121 may be, for example, seven. In this embodiment, one of the divergence parts 121 in the second liquid cooling module 12b and one of the divergence parts 121 in the third liquid cooling module 12c are integrally formed as one single structure. Similarly, another divergence part 121 in the second liquid cooling module 12b and another divergence part 121 in the third liquid cooling module 12c are also integrally formed as one single structure. However, the present disclosure is not limited to this configuration.

The second liquid cooling plates 122 may be, for example, made of SAE 304 stainless steel, which enhances durability and heat dissipation performance. In each liquid cooling module 12, the quantity of the second liquid cooling plates 122 may be, for example, seven. These second liquid cooling plates 122 are disposed between the two divergence parts 121 and are in fluid communication with the divergence parts 121 via the divergence holes 1211. Specifically, each second liquid cooling plate 122 has two protruding tabs 1221 respectively at two opposite ends thereof. These protruding tabs 1221 of the second liquid cooling plates 122 are inserted into the divergence holes 1211 to secure the connection between the second liquid cooling plates 122 and the divergence parts 121. The protruding tabs 1221 and the divergence parts 121 are connected by welding to enhance the sealing and structural integrity of the connection between the second liquid cooling plates 122 and the divergence parts 121. However, the present invention is not limited to a welded connection method.

The second liquid cooling plates 122 have internal flow channels for the passage of coolant (e.g., water, not shown in the drawings), as illustrated by the dashed lines inside the second liquid cooling plates 122 in FIG. 3. The second liquid cooling plates 122 are configured to thermally contact a plurality of second heating elements 22, wherein the second heating elements 22 may be, for example, DIMM-standard memory modules. Alternatively, it can be stated that the second liquid cooling plates 122 are configured to clamp the second heating elements 22. Or, in another interpretation, each second heating element 22 is disposed between two adjacent second liquid cooling plates 122. As a result, the second liquid cooling plates 122 can absorb the heat generated by the second heating elements 22 during operation, preventing heat accumulation around the second heating elements 22 that could otherwise affect their normal functioning.

Moreover, each second liquid cooling plate 122 has a clearance groove 1222 to prevent interference with protruding portions (not separately numbered) of the second heating elements 22 and to facilitate the installation and removal of the second heating elements 22. Please be noted that the clearance grooves 1222 are optional. In some embodiments of the present disclosure, the second liquid cooling plates may not have any clearance groove. Furthermore, during the installation or removal of the second heating elements 22, there is no need to remove the liquid cooling modules 12, thereby preventing the risk of coolant leakage.

In each liquid cooling module 12, the quantity of the flexible thermal conductive pads 123 may be, for example, seven. These flexible thermal conductive pads 123 may be, for example, made of polyimide (PI) and have flexibility. The flexible thermal conductive pads 123 are respectively disposed on the outer sides of the second liquid cooling plates 122. With the design of the flexible thermal conductive pads 123, the second heating elements 22, which may have uneven surfaces, can tightly conform to the flexible thermal conductive pads 123. Through the flexible thermal conductive pads 123, efficient heat exchange with the second liquid cooling plates 122 is achieved, thereby enhancing thermal conduction between the second liquid cooling plates 122 and the second heating elements 22.

The quantity of the communication pipes 13 may be, for example, two. The communication pipes 13 may be, for example, made of polytetrafluoroethylene (PTFE) and have flexibility. The communication pipes 13 respectively enable fluid communications between the first liquid cooling module 12a and the second liquid cooling module 12b and between the third liquid cooling module 12c and the fourth liquid cooling module 12d.

Please be noted that the quantities of the aforementioned components are not intended to limit the present disclosure.

With the above configuration, the first liquid cooling plates 11 and the liquid cooling modules 12 can be connected in series and in fluid communication with each other. Furthermore, the liquid cooling system 10 forms only one single series-connected fluid passage, consisting of the front first liquid cooling plate 11a, the rear first liquid cooling plate 11b, the first liquid cooling module 12a, the second liquid cooling module 12b, the third liquid cooling module 12c, and the fourth liquid cooling module 12d.

Specifically, as indicated by arrow AA in FIG. 1, the liquid cooling system 10 allows coolant to flow into the front first liquid cooling plate 11a. After completing heat exchange with one of the first heating elements 20, the coolant exits the front first liquid cooling plate 11a. Then, as indicated by arrow BB in FIG. 1, the coolant flows into the rear first liquid cooling plate 11b. The coolant then exits the rear first liquid cooling plate 11b after completing heat exchange with another first heating element 20.

Then, as indicated by arrow CC in FIG. 1, the coolant flows into one of the divergence parts 121 of the first liquid cooling module 12a. Then, as indicated by arrow DD in FIG. 1, the coolant flows through the second liquid cooling plates 122 of the first liquid cooling module 12a to complete heat exchange with the second heating elements 22, after which it flows into the other divergence part 121 of the first liquid cooling module 12a. Subsequently, as indicated by arrow EE in FIG. 1, the coolant flows into one of the divergence parts 121 of the second liquid cooling module 12b via one of the communication pipes 13.

Then, as indicated by arrow FF in FIG. 1, the coolant flows through the second liquid cooling plates 122 of the second liquid cooling module 12b to complete heat exchange with the second heating elements 22. The coolant then flows into the other divergence part 121 of the second liquid cooling module 12b. Then, as indicated by arrow GG in FIG. 1, the coolant flows from the other divergence part 121 of the second liquid cooling module 12b into one of the divergence parts 121 of the third liquid cooling module 12c.

Then, as indicated by arrow HH in FIG. 1, the coolant flows through the second liquid cooling plates 122 of the third liquid cooling module 12c to complete heat exchange with the second heating elements 22, after which it flows into the other divergence part 121 of the third liquid cooling module 12c. Then, as indicated by arrow II in FIG. 1, the coolant flows into one of the divergence parts 121 of the fourth liquid cooling module 12d via another communication pipe 13.

Please be noted that in the second liquid cooling module 12b and the third liquid cooling module 12c, one pair of integrally formed divergence parts 121 are internally directly connected in fluid communication, allowing the coolant to flow as indicated by arrow GG. However, another pair of integrally formed divergence parts 121 in the second liquid cooling module 12b and the third liquid cooling module 12c are not internally directly connected in fluid communication, so the flow path indicated by arrow EE cannot directly connect to the flow path indicated by arrow II.

Then, as indicated by arrow JJ in FIG. 1, the coolant flows through the second liquid cooling plates 122 of the fourth liquid cooling module 12d to complete heat exchange with the second heating elements 22, after which it flows into the other divergence part 121 of the fourth liquid cooling module 12d. Then, as indicated by arrow KK in FIG. 1, the coolant exits the fourth liquid cooling module 12d.

According to the liquid cooling system discussed above, in addition to using the first liquid cooling plates to absorb the heat generated by the first heating elements, the first liquid cooling plates are also connected in series to the second liquid cooling plates. This design enables the second liquid cooling plates to absorb the heat generated by the second heating elements during operation, thereby preventing heat accumulation around the second heating elements that could otherwise affect their normal functioning. Simulation tests have checked that the liquid cooling system of the present disclosure can maintain the working temperature of the second heating elements below 67.3° C.

Further, the liquid cooling system forms only one single series-connected fluid passage. Furthermore, the liquid cooling system with the series-connected fluid passage can increase the temperature difference between the inlet and outlet of the coolant, thereby enhancing heat exchange efficiency and reducing the operating costs of the liquid cooling system.

Moreover, the clearance grooves of the second liquid cooling plates prevent interference with protruding portions of the second heating elements, facilitating the installation and removal of the second heating elements. Moreover, the second heating elements can be installed or removed without removing the liquid cooling modules, thereby preventing the risk of coolant leakage.

Furthermore, the design of the flexible thermal conductive pads allows them to conform tightly to the uneven surfaces of the second heating elements. Through the flexible thermal conductive pads, efficient heat exchange with the second liquid cooling plates is achieved, thereby enhancing thermal conduction between the second liquid cooling plates and the second heating elements.

The embodiments are chosen and described in order to best explain the principles of the present disclosure and its practical applications, to thereby enable others skilled in the art best utilize the present disclosure and various embodiments with various modifications as are suited to the particular use being contemplated. It is intended that the scope of the present disclosure is defined by the following claims and their equivalents.

What is claimed is:

1. A liquid cooling system, comprising:
a plurality of first liquid cooling plates configured to respectively thermally contact a plurality of first heating elements, wherein the plurality of first liquid cooling plates are connected in series and in fluid communication with each other; and
a plurality of liquid cooling modules connected in series and in fluid communication with each other, each of the plurality of liquid cooling modules comprising:
two divergence parts in fluid communication with the plurality of first liquid cooling plates, each of the two divergence parts having a plurality of divergence holes; and
a plurality of second liquid cooling plates configured to thermally contact a plurality of second heating elements, wherein the plurality of second liquid cooling plates are disposed between the two divergence parts and are in fluid communication with the two divergence parts via the plurality of divergence holes, respectively;
wherein the plurality of first liquid cooling plates and the plurality of liquid cooling modules are connected in series and in fluid communication with each other.

2. The liquid cooling system according to claim 1, wherein each of the plurality of second liquid cooling plates has two protruding tabs respectively at two opposite ends thereof, and the protruding tabs of the plurality of second liquid cooling plates are inserted into the plurality of divergence holes to secure connections between the plurality of second liquid cooling plates and the divergence parts.

3. The liquid cooling system according to claim 2, wherein the protruding tabs and the divergence parts are connected by welding to enhance sealing and structural integrity of the connections between the plurality of second liquid cooling plates and the divergence parts.

4. The liquid cooling system according to claim 1, wherein the plurality of second liquid cooling plates are configured to clamp the plurality of second heating elements, and each of the plurality of second liquid cooling plates has a clearance groove to prevent interference with protruding portions of the plurality of second heating elements.

5. The liquid cooling system according to claim 1, wherein each of the plurality of liquid cooling modules further comprises a plurality of flexible thermal conductive pads which have flexibility and are respectively disposed on the plurality of second liquid cooling plates to enhance thermal conduction between the plurality of second liquid cooling plates and the plurality of second heating elements.

6. The liquid cooling system according to claim 5, wherein the plurality of flexible thermal conductive pads are made of polyimide.

7. The liquid cooling system according to claim 1, wherein the plurality of first liquid cooling plates comprise a front first liquid cooling plate and a rear first liquid cooling plate, and the plurality of liquid cooling modules comprise a first liquid cooling module, a second liquid cooling module, a third liquid cooling module, and a fourth liquid cooling module, the liquid cooling system is configured to allow a coolant to sequentially flow through the front first liquid cooling plate, the rear first liquid cooling plate, the first liquid cooling module, the second liquid cooling module, the third liquid cooling module, and the fourth liquid cooling module.

8. The liquid cooling system according to claim 7, wherein one of the two divergence parts of the second liquid cooling module and one of the two divergence parts of the third liquid cooling module are integrally formed as one single structure, and another one of the two divergence parts of the second liquid cooling module and another one of the two divergence parts of the third liquid cooling module are integrally formed as one single structure.

9. The liquid cooling system according to claim 7, further comprising a plurality of communication pipes which are made of polytetrafluoroethylene (PTFE) and have flexibility, wherein the plurality of communication pipes respectively enable fluid communications between the first liquid cooling module and the second liquid cooling module and between the third liquid cooling module and the fourth liquid cooling module.

10. The liquid cooling system according to claim 7, wherein the front first liquid cooling plate, the rear first liquid cooling plate, the first liquid cooling module, the second liquid cooling module, the third liquid cooling module, and the fourth liquid cooling module of the liquid cooling system form only one single series-connected fluid passage.
